(19) United States
(12) Patent Application Publication
(10) Pub. No.: US 2003/0148592 A1
(43) Pub. Date: Aug. 7, 2003

(54) Method for bonding a pair of silicon wafers together, and a semiconductor wafer

(76) Inventors: William Andrew Nevin, Portadown (GB); Paul Damien McCann, Jordanstown (GB); Garry Patrick O'Neill, Coagh (GB)

Correspondence Address: IANDIORIO & TESKA, INTELLECTUAL PROPERTY LAW ATTORNEYS, 260 BEAR HILL ROAD, WALTHAM, MA, 02451-1018, US

(21) Appl. No.: 10/282,693

(22) Filed: Oct. 29, 2002

Related U.S. Application Data
(60) Provisional application No. 60/350,976, filed on Oct. 29, 2001.

(51) Int. Cl. H01L 21/30; H01L 21/46

(52) U.S. Cl. 438/455

(57) ABSTRACT

A method for bonding a pair of silicon wafers (2,3) together to form a semiconductor wafer (1) wherein an interface surface (5) of one of the silicon wafers (3) is pretreated by an ion implantation or diffusion process prior to bonding of the silicon wafers (2,3). The method includes subjecting the pretreated interface surface (5) to an initial anneal step at approximately 700° C. for 60 minutes for recrystallising the interface surface, and then subjecting both interface surfaces (4,5) to two cleaning steps with respective first and second cleaning solutions, neither of which contain sulphuric acid. The first cleaning solution comprises hydrogen peroxide, ammonia and water, while the second cleaning solution comprises hydrofluoric acid and water. The respective interface surfaces (4,5) are rinsed with water after each cleaning step, and the silicon wafers (2,3) are bonded by anneal bonding at a temperature of the order of 1,150° C. for approximately 60 minutes.

### RELATED APPLICATIONS

This application claims priority of U.S. Provisional Application No. 60/350,976, filed on Oct. 29, 2001, and entitled, “METHOD FOR BONDING A PAIR OF SILICON WAFERS TOGETHER,” incorporated by reference herein.

### FIELD OF THE INVENTION

The present invention relates to a method for bonding a pair of silicon wafers together to form a semiconductor wafer wherein at least one of the silicon wafers has been subjected to ion implantation or diffusion prior to bonding, and the invention also relates to a semiconductor wafer formed by a pair of silicon wafers bonded together.

### BACKGROUND TO THE INVENTION

Methods for bonding silicon wafers to form a semiconductor wafer by bonding interface surfaces of the respective silicon wafers directly together are known. In general, the surfaces which are to form the interface surfaces of the silicon wafers which are to be bonded together are subjected to a cleaning process which typically is a three step process. In the first step of the cleaning process the respective interface surfaces are subjected to a Sulphuric acid-hydrogen Peroxide Mixture (SPM) clean, and are then subjected to a water rinse. In the second step of the cleaning process the respective interface surfaces are subjected to a standard RCA (Radio Corporation of America) clean, which typically is referred to as an SC1 clean. The interface surfaces are then subsequently rinsed. In the third step of the cleaning process the respective interface surfaces are subjected to a final clean with a dilute solution of hydrofluoric acid, and may subsequently be subjected to a final water rinse. In the SPM clean of the first step the respective interface surfaces are cleaned with a cleaning solution which comprises a dilute mixture of sulphuric acid and hydrogen peroxide. In the second SC1 cleaning step the respective interface surfaces are cleaned with a cleaning solution which comprises a dilute mixture of hydrogen peroxide and ammonia. Where the interface surfaces are subjected to a final rinse after the interface surfaces have been subjected to the third cleaning step with the dilute solution of hydrofluoric acid, the final rinse is a thorough water rinse for removing any remaining residues of the respective cleaning solutions from the interface surfaces. The cleaned and rinsed interface surfaces are then abutted together and subjected to a high temperature anneal at a temperature in the range of 1,000° C. to 1,200° C. for fusion bonding the respective silicon wafers together. In general, silicon wafers can be bonded together relatively successfully with this process.

However, it has been found that where one or both of the interface surfaces of the respective silicon wafers have been subjected to ion implantation and/or diffusion of dopant species, such as phosphorous, boron, arsenic or antimony, in order to improve the electrical characteristics of the silicon wafer, known bonding methods for bonding silicon wafers together are inadequate. In general, it has been found that voids form between the interface surfaces being bonded together during the high temperature anneal fusion bonding step. This is unacceptable, since in the areas of the voids the interface surfaces remain unbonded, and subsequent fracturing of one or both of the silicon wafers can occur at the unbonded areas, thus leading to loss of the active silicon, and subsequent rejection of a semiconductor device formed from such bonded silicon wafers, as well as causing contamination of a production line. Even without fracturing of the silicon in the unbonded areas, the voids can cause failure of semiconductor devices formed on the semiconductor wafer through current leakage. The voids also lead to dopant leakage during production processing. It has also been found that the higher the level of ion implantation or diffusion into one or both of the silicon wafers through the interface surface or surfaces, the greater will be the number of voids formed.

There is therefore a need for a method for bonding silicon wafers together where at least one of the silicon wafers has been subjected to ion implantation or diffusion prior to bonding.

The present invention is directed towards providing such a method, and a semiconductor wafer formed according to the method.

### SUMMARY OF THE INVENTION

According to the invention there is provided a method for bonding a pair of silicon wafers together at adjacent abutting interface surfaces of the respective silicon wafers to form a semiconductor wafer, wherein at least one of the interface surfaces has been pretreated by being subjected to one of an ion implantation process and a diffusion process prior to bonding, the method comprising the steps of:

subjecting each pretreated interface surface to at least one cleaning step with a cleaning solution, the cleaning solution of each cleaning step being substantially non-absorbable through the interface surface,

abutting the respective interface surfaces together, and

subjecting the silicon wafers to anneal bonding for bonding the abutting interface surfaces together.

Preferably, the constituents of the cleaning solution of each cleaning step are non-absorbable through each pretreated interface surface. Advantageously, the cleaning solution of each cleaning step is a solution which does not contain sulphuric acid, and ideally, the cleaning solution of each cleaning step is a solution which does not contain sulphuric acid or its species.

In one embodiment of the invention each pretreated interface surface is subjected to two cleaning steps, in one of the two cleaning steps the cleaning solution comprising hydrogen peroxide and ammonia, and in the other of the two cleaning steps the cleaning solution comprising hydrofluoric acid. Preferably, the cleaning solution comprising hydrogen peroxide and ammonia comprises the hydrogen perioxide and ammonia in effective amounts for cleaning each pretreated interface surface.

Advantageously, the cleaning solution comprising hydrogen peroxide and ammonia comprises hydrogen peroxide in an amount in the range of 1% to 30% by volume of the cleaning solution, and ammonia in an amount in the range of 0.005% to 14% by volume of the cleaning solution. Advantageously, the cleaning solution comprising hydrogen peroxide and ammonia comprises hydrogen peroxide in an amount in the range of 10% to 20% by volume of the cleaning solution, and ammonia in an amount in the range of 0.01% to 1% by volume of the cleaning solution. Ideally, the cleaning solution comprising hydrogen peroxide and ammonia comprises hydrogen peroxide in an amount in the order of 17% by volume of the cleaning solution, and ammonia in an amount in the range of 0.01% to 0.02% by volume of the cleaning solution. Preferably, the cleaning solution comprising hydrofluoric acid comprises the hydrofluoric acid in an effective amount for cleaning each pretreated interface surface.

Advantageously, the cleaning solution comprising hydrofluoric acid comprises hydrofluoric acid in an amount in the range of 0.05% to 20% by volume of the cleaning solution. Advantageously, the cleaning solution comprising hydrofluoric acid comprises hydrofluoric acid in an amount in the range of 0.2% to 10% by volume of the cleaning solution. Ideally, the cleaning solution comprising hydrofluoric acid comprises hydrofluoric acid in an amount in the range of 0.2% to 1% by volume of the cleaning solution.

In one embodiment of the invention the balance of each cleaning solution is made up with water.

In another embodiment of the invention each pretreated interface surface is subjected to the cleaning step with the cleaning solution comprising hydrogen peroxide and ammonia before being subjected to the cleaning step with the cleaning solution comprising hydrofluoric acid.

Preferably, each pretreated interface surface is subjected to a water rinse after being subject to each cleaning step for removing residue of the cleaning solutions.

In one embodiment of the invention each pretreated interface surface is subjected to an initial anneal step for recrystallising the interface surface prior to cleaning, and preferably, each pretreated interface surface is subjected to an initial anneal step at an effective temperature for recrystallising the interface surface prior to cleaning., and advantageously, the initial anneal step is carried out at a temperature in the range of 650° C. to 1,050° C. Preferably, the initial anneal step is carried out at a temperature in the range of 680° C. to 850° C. Ideally, the initial anneal step is carried out at a temperature in the range of 700° C. to 750° C.

In one embodiment of the invention each pretreated interface surface is subjected to the initial anneal step for a time period sufficient for recrystallising the interface surface, and preferably, the initial anneal step is carried out for a time period in the range of 30 minutes to 180 minutes. Advantageously, the initial anneal step is carried out for a time period in the range of 30 minutes to 120 minutes. Ideally, the initial anneal step is carried out for a time period of approximately 60 minutes.

In one embodiment of the invention each pretreated interface surface is subjected to polishing after recrystallising of the interface surface by the initial anneal step.

In another embodiment of the invention the anneal bonding for bonding the respective silicon wafers together is carried out at an effective anneal bonding temperature to provide adequate bonding of the silicon wafers, and advantageously, the anneal bonding for bonding the respective silicon wafers together is carried out at an anneal bonding temperature of at least 1,000° C. Preferably, the anneal bonding temperature is in the range of 1,150° C. to 1,200° C.

Preferably, the silicon wafers are subjected to anneal bonding for a time period sufficient for adequate bonding of the wafers to take place. Advantageously, the silicon wafers are subjected to anneal bonding for a time period in the range of 15 minutes to 300 minutes. Preferably, the silicon wafers are subjected to anneal bonding for a time period in the range of 30 minutes to 250 minutes. Preferably, the silicon wafers are subjected to anneal bonding for a time period of approximately 60 minutes.

In one embodiment of the invention the interface surface of the at least one silicon wafer is pretreated by being subjected to ion implantation for improving the electrical characteristics of the wafer.

In another embodiment of the invention the interface surface of the at least one silicon wafer is pretreated by being subjected to diffusion for improving the electrical characteristics of the wafer.

Additionally the invention provides a semiconductor wafer comprising a pair of silicon wafers bonded together by anneal bonding, the bonded silicon wafers each defining an interface surface abutting the interface surface of the other silicon wafer, at least one of the interface surfaces having been subjected to a pretreatment prior to bonding by one of an ion implantation process and a diffusion process, each pretreated interface surface having been subjected to at least one cleaning step with a cleaning solution prior to the silicon wafers being subjected to the anneal bonding, the cleaning solution of each cleaning step being substantially non-absorbable through the interface surface.

### ADVANTAGES OF THE INVENTION

The advantages of the invention are many. It has been found that the bonded interface surfaces of the semiconductor wafer are void free or virtually void free. The absence of voids, or the minimisation of voids between the respective interface surfaces avoids any danger of subsequent fracturing of the silicon wafers of the semiconductor wafer during subsequent processing. Additionally, the absence of voids avoids any danger of current leakages from components subsequently fabricated in the semiconductor wafer. The absence of voids also avoids any danger of dopant leakage, or uneven diffusion which would otherwise occur during subsequent processing and fabrication of components in the semiconductor wafer. The absence of voids also avoids any danger of photoresist streaking and uneven coverage during subsequent processing and fabrication of components on the semiconductor wafer.

The invention will be more clearly understood from the following description of some preferred embodiments thereof, which are given by way of example only, in the following examples, and with reference to the accompanying drawings.

### BRIEF DESCRIPTION OF THE DRAWINGS

FIG. 1 is a top plan view of a semiconductor wafer formed by bonding a pair of silicon wafers by a method according to the invention,

FIG. 2 is a side elevational view of the semiconductor wafer of FIG. 1,

FIG. 3(a) is a scanning acoustic micrograph of a semiconductor wafer formed by bonding a pair of silicon wafers by a method according to the invention,

FIG. 3(b) is a micrograph similar to FIG. 3(a) of a semiconductor wafer formed by bonding a similar pair of semiconductor wafers to those of FIG. 3(a) by a prior art method,

FIG. 4(a) is a micrograph of a semiconductor wafer formed by bonding a pair of silicon wafers by a method according to the invention,

FIG. 4(b) is a micrograph similar to FIG. 4(a) of a semiconductor wafer formed by bonding a similar pair of semiconductor wafers to those of FIG. 4(a) by a prior art method,

FIG. 5(a) is a micrograph of a semiconductor wafer formed by bonding a pair of silicon wafers by a method according to the invention, and

FIG. 5(b) is a micrograph similar to FIG. 5(a) of a semiconductor wafer formed by bonding a similar pair of semiconductor wafers to those of FIG. 5(a) by a prior art method.

### DETAILED DESCRIPTION OF PREFERRED EMBODIMENTS OF THE INVENTION

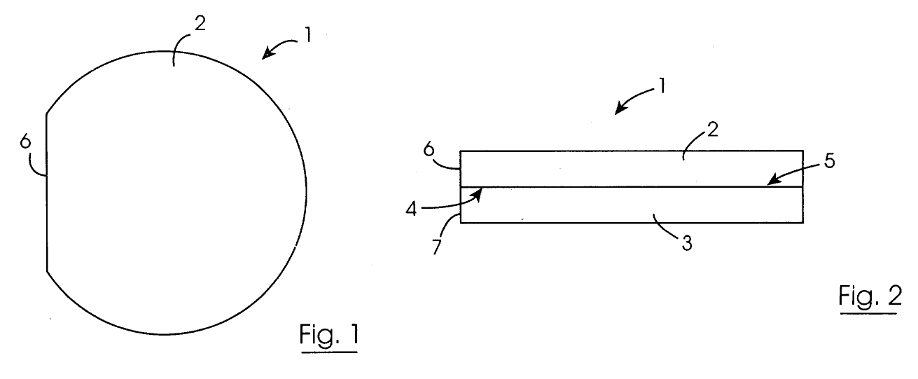

Referring to the drawings, and initially to FIGS. 1 and 2, there is illustrated a semiconductor wafer according to the invention, indicated generally by the reference numeral 1, formed from a pair of silicon wafers, namely, a first silicon wafer 2 and a second silicon wafer 3, which are fusion bonded at respective interface surfaces 4 and 5. The silicon wafers 2 and 3 are of 100 mm diameter having respective alignment edges 6 and 7.

The method according to the invention for forming the semiconductor wafer 1 is described below with reference to the examples, in which the preparation of a number of semiconductor wafers similar to the semiconductor wafer 1 is described. In each example a semiconductor wafer according to the invention was prepared from a pair of silicon wafers which were bonded together using the method according to the invention. Additionally, in each example a semiconductor wafer was prepared from a similar pair of silicon wafers which were bonded together using a prior art method. The semiconductor wafer of each example formed by the method according to the invention was compared with the corresponding semiconductor wafer formed by the prior art method, and micrographs of the two semiconductor wafers of each example were prepared by subjecting the respective semiconductor wafers to scanning acoustic microscopy (SAM) imaging for detecting the presence of voids between the bonded interface surfaces. The results of the SAM imaging of the respective semiconductor wafers are discussed in the examples.

The first silicon wafers 2 from which the semiconductor wafers 1 according to the invention, and the semiconductor wafers according to the prior art were prepared were similar for all the examples, and were silicon wafers having the following specification: 0.03 to 0.06 ohm.cm, antimony doped Czochralski silicon, having a crystal plane orientation <111>. The second silicon wafers 3 from which the semiconductor wafers 1 according to the invention and the semiconductor wafers according to the prior art were prepared were similar for all the examples, but the interface surfaces 5 of the second silicon wafers 3 were pretreated by being subjected to arsenic ion implantation for improving the electrical characteristics of the wafer, and the level of ion implantation to which the interface surfaces were subject differed from example to example as will be described below. The second silicon wafers 3 were of the following specification: 2,000 to 4,000 ohm.cm, phosphorous doped float zone silicon, having a crystal plane orientation <111>. The interface surfaces 4 of the first silicon wafers 2 from which the semiconductor wafers according to the invention and according to the prior art of the examples were prepared were not subjected to pretreatment by ion implantation.

The method according to the invention used for bonding the pairs of silicon wafers 2 and 3 to form the semiconductor wafers 1 according to the invention of the following examples was similar for each example. In accordance with the method of the invention, the second silicon wafers 3, the interface surfaces 5 of which had been subjected to ion implantation were subjected to an initial low temperature anneal step for recrystalising the ion implanted interface surfaces 5. The low temperature anneal step was carried out at a temperature of approximately 700° C. for a time period in the order of 60 minutes, and was carried out in a horizontal quartz diffusion furnace, in a nitrogen atmosphere.

The interface surfaces 4 and 5 of the first and second silicon wafers 2 and 3, respectively, which were to be bonded together to form the semiconductor wafers 1 according to the invention were then subjected to two cleaning steps whereby the respective interface surfaces 4 and 5 were cleaned with two cleaning solutions, neither of which contained sulphuric acid or its species. In the first cleaning step the respective interface surfaces 4 and 5 were subjected to cleaning with a first cleaning solution which comprised a dilute solution of hydrogen peroxide and ammonia in the following proportions by volume of the total solution:

| | |
|---|---|
| Hydrogen peroxide | 17% |
| Ammonia | 0.02% |
| Water | 83% |

When the first cleaning step had been completed, the respective interface surfaces 4 and 5 were subjected to a first water rinse for thoroughly removing any residue of the first cleaning solution, and the interface surfaces 4 and 5 were then subjected to the second cleaning step.

In the second cleaning step the respective interface surfaces 4 and 5 were subjected to cleaning with a second cleaning solution which comprised a dilute solution of hydrofluoric acid in the following proportions by volume of the total solution:

| | |
|---|---|
| Hydrofluoric acid | 0.3% |
| Water | 99.7% |

When the second cleaning step had been completed, the respective interface surfaces 4 and 5 were subjected to a second water rinse for thoroughly removing residue of the second cleaning solution from the respective surfaces. Additionally, the second water rinse was sufficient for removing any residual residue of the first cleaning solution which had not already been removed during the first water rinse.

The two silicon wafers 2 and 3 were then spin-dried until the respective interface surfaces 4 and 5 were thoroughly dried. The first and second silicon wafers 2 and 3 were aligned with their respective alignment edges 6 and 7 aligned with each other, and the interface surfaces 4 and 5 were then abutted together, and the aligned abutting first and second silicon wafers 2 and 3 were placed in the horizontal diffusion quartz furnace in a nitrogen atmosphere diluted with less than 5% oxygen, and were subjected to a fusion bond anneal at a temperature of the order of 1,150° C. for a time period in the region of 60 minutes for fusion bonding the first and second silicon wafers 2 and 3 together.

After the anneal fusion bonding step had been completed and the first and second silicon wafers 2 and 3 had been adequately bonded together to form the semiconductor wafers 1 according to the invention, the semiconductor wafers 1 were removed from the furnace.

The method according to the prior art which was used for bonding the corresponding pair of silicon wafers in each example for forming the corresponding prior art semiconductor wafers was as follows. The silicon wafers which had been pretreated by ion implantation were subjected to an initial low temperature anneal step, which was similar to that to which the second silicon wafers 3 of the semiconductor wafers 1 according to the invention had been subjected. The interface surfaces of both silicon wafers were then subjected to a three step cleaning process. The first cleaning step to which the interface surfaces of the silicon wafers were subjected was a standard SPM clean with a cleaning solution comprising the following constituents in the following proportions by volume of the total solution:

| | |
|---|---|
| Sulphuric acid | 80% |
| Hydrogen peroxide | 20% |

After the first cleaning step had been completed, the respective interface surfaces were subjected to a water rinse for removing any residues of the cleaning solution of the first cleaning step, and the interface surfaces were then subjected to the second cleaning step.

In the second cleaning step the interface surfaces of the silicon wafers were subjected to a standard RCA clean, namely, an SC1 clean with a cleaning solution, which was similar to the first cleaning solution to which the first and second silicon wafers 2 and 3 of the semiconductor wafer 1 according to the invention were subjected, and which comprised the following constituents in the following proportions by volume of the total solution:

| | |
|---|---|
| Hydrogen peroxide | 17% |
| Ammonia | 0.02% |
| Water | 83% |

After the second cleaning step the respective interface surfaces were subjected to a water rinse for removing any residue of the cleaning solution of the second cleaning step, and the interface surfaces were then subjected to the third cleaning step.

In the second cleaning step the interface surfaces of the two silicon wafers were subjected to cleaning with a dilute solution of hydrofluoric acid, which was similar to the second cleaning solution to which the first and second silicon wafers 2 and 3 of the semiconductor wafer 1 according to the invention were subjected, and which comprised the following constituents in the following proportions by volume of the total solution:

| | |
|---|---|
| Hydrofluoric acid | 0.3% |
| Water | 99.7% |

After the third cleaning step the interface surfaces were subjected to a thorough final water rinse for removing residue of the cleaning solution of the third cleaning step and any remaining residues of the cleaning solutions of the first and second cleaning steps. The silicon wafers were then spin dried until the respective interface surfaces were thoroughly dry, and the interface surfaces were then abutted together. The two silicon wafers of each prior art semiconductor wafer with their respective interface surfaces abutting together and their alignment edges aligned were then placed in the horizontal diffusion quartz furnace in a nitrogen atmosphere diluted with less than 5% oxygen, and were subjected to a fusion bond anneal at a temperature in the order of 1,150° C., which was similar to that to which the corresponding semiconductor wafer 1 according to the invention had been subjected for a similar time period in the region of 60 minutes. On completion of fusion bonding the prior art semiconductor wafers were removed from the oven.

In carrying out both the method according to the invention and the prior art method, the steps in the respective methods, after the initial low temperature anneal had been completed, were carried out one after the other, and immediately one step had been completed, the next step was commenced. In other words, as soon as each cleaning step had been completed, the following rinse step was commenced, and as soon as the last rinse had been completed, the silicon wafers were subjected to the spin dry, and on the completion of spin dry, the wafers were abutted together with their interface surfaces abutting, and were immediately transferred to the oven for anneal fusion bonding. It was not necessary to commence the first cleaning steps immediately after the initial low temperature anneal had been completed. The cleaning, rinsing and spin drying steps of both the bonding method according to the invention and the prior art bonding method were carried out in air.

### EXAMPLE 1

In this example the first and second silicon wafers 2 and 3 from which the semiconductor wafer 1 according to the invention and the prior art semiconductor wafer were prepared were as discussed above. The interface surfaces 5 of the two second silicon wafers 3 were subjected to the ion implanting with arsenic ions at a dose of 5×10¹³ atoms/cm², 50 keV energy. The first and second silicon wafers 2 and 3 from which the semiconductor wafer 1 according to the invention was prepared were prepared and bonded by the method according to the invention described above. The interface surface 5 of the second silicon wafer 3 was initially subjected to the initial low temperature anneal, and the interface surfaces 4 and 5 of the first and second silicon wafers 2 and 3 were then subjected to the first and second cleaning steps and the two water rinses, and then anneal fusion bonded.

The first and second silicon wafers of the prior art semiconductor wafer were prepared and bonded using the prior art method discussed above. The silicon wafer the interface surface of which had been subjected to ion implanting was subjected to the initial low temperature anneal. The interface surfaces of the respective silicon wafers were then subjected to the three cleaning steps and the three rinses of the prior art method discussed above, and were then anneal fusion bonded.

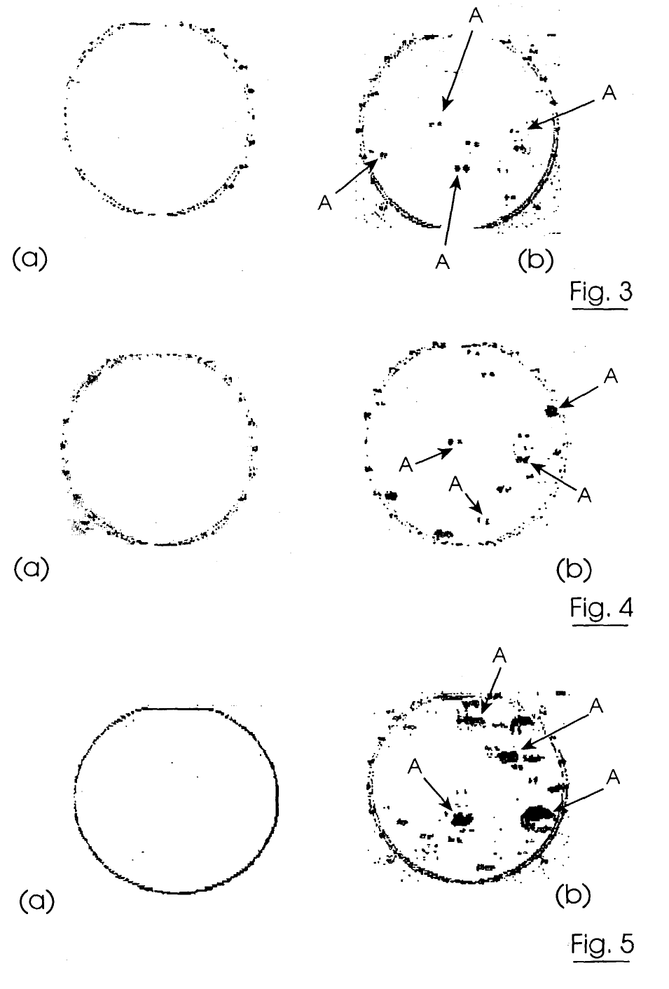

The micrograph of FIG. 3(a) of the semiconductor wafer 1 according to the invention, and the micrograph of FIG. 3(b) of the prior art semiconductor wafer were prepared by SAM imaging. The micrograph of FIG. 3(a) shows that the semiconductor wafer according to the invention is void free. The micrograph of FIG. 3(b) of the prior art semiconductor wafer shows a number of voids formed between the interface surfaces of the silicon wafers. Some of the voids are indicated by the reference letter A.

### EXAMPLE 2

In this example the first and second silicon wafers 2 and 3 from which the semiconductor wafer 1 according to the invention and the prior art semiconductor wafer were prepared were as discussed above. The interface surfaces 5 of the two second silicon wafers 3 were subjected to the ion implanting with arsenic ions at a dose of 1×10¹⁴ atoms/cm², 50 keV energy. The first and second silicon wafers 2 and 3 from which the semiconductor wafer 1 according to the invention was prepared were prepared and bonded by the method according to the invention described above. The interface surface 5 of the second silicon wafer 3 was initially subjected to the initial low temperature anneal, and the interface surfaces 4 and 5 of the first and second silicon wafers 2 and 3 were then subjected to the first and second cleaning steps and the two water rinses, and then anneal fusion bonded.

The first and second silicon wafers of the prior art semiconductor wafer were prepared and bonded using the prior art method discussed above. The silicon wafer the interface surface of which had been subjected to ion implantation was subjected to the initial low temperature anneal. The interface surfaces of the respective silicon wafers were then subjected to the three cleaning steps and the three rinses of the prior art method discussed above, and were then anneal fusion bonded.

The micrograph of FIG. 4(a) of the semiconductor wafer 1 according to the invention, and the micrograph of FIG. 4(b) of the prior art semiconductor wafer were prepared by SAM imaging. The micrograph of FIG. 4(a) shows that the semiconductor wafer according to the invention is void free. The micrograph of FIG. 4(b) of the prior art semiconductor wafer shows a number of voids formed between the interface surfaces of the silicon wafers. Some of the voids are indicated by the reference letter A.

### EXAMPLE 3

In this example the first and second silicon wafers 2 and 3 from which the semiconductor wafer 1 according to the invention and the prior art semiconductor wafer were prepared were as discussed above. The interface surfaces 5 of the two second silicon wafers 3 were subjected to the ion implanting with arsenic ions at a dose of 2.5×10¹⁵ atoms/cm², 50 keV energy. The first and second silicon wafers 2 and 3 from which the semiconductor wafer 1 according to the invention was prepared were prepared and bonded by the method according to the invention described above. The interface surface 5 of the second silicon wafer 3 was initially subjected to the initial low temperature anneal, and the interface surfaces 4 and 5 of the first and second silicon wafers 2 and 3 were then subjected to the first and second cleaning steps and the two water rinses, and then anneal fusion bonded.

The first and second silicon wafers of the prior art semiconductor wafer were prepared and bonded using the prior art method discussed above. The silicon wafer the interface surface of which had been subjected to ion implanting was subjected to the initial low temperature anneal. The interface surfaces of the respective silicon wafers were subjected to the three cleaning steps and the three rinses of the prior art method discussed above, and were then anneal fusion bonded.

The micrograph of FIG. 5(a) of the semiconductor wafer 1 according to the invention, and the micrograph of FIG. 5(b) of the prior art semiconductor wafer were prepared by SAM imaging. The micrograph of FIG. 5(a) shows that the semiconductor wafer according to the invention is void free. The micrograph of FIG. 5(b) of the prior art semiconductor wafer shows a number of voids formed between the interface surfaces of the silicon wafers. Some of the voids are indicated by the reference letter A.

Accordingly, it can be seen from Examples 1 to 3 and the micrographs of FIGS. 3(a) and 3(b) to 5 (a) and 5 (b) that the semiconductor wafers formed by bonding the silicon wafers using the method according to the invention avoids the formation of voids, while all the semiconductor wafers prepared using the prior art method displayed the existence of voids between the interface surfaces. Further, it can be seen that the higher the arsenic ion implantation dose the greater the number of voids formed in the prior art semiconductor wafers. The semiconductor wafer of Example 3 in which the second silicon wafer was implanted at a dose of 2.5×10¹⁵ atoms/cm², 50 keV energy is displaying considerably more voids A than the prior art semiconductor wafer of Example 2 in which the second silicon wafer was implanted at a dose of 1×10¹⁴ atoms/cm², 50 keV energy, and the prior art semiconductor wafer of the second example displays marginally more voids, and in particular, larger voids than the prior art semiconductor wafer of Example 1 which was implanted at a dose of 5×10¹³ atoms/cm², 50 keV energy. However, using the bonding method according to the invention avoided the formation of voids between the interface surfaces irrespective of the arsenic ion implantation dose.

It should be noted that the disturbance displayed in the micrograph which defines the periphery of both the semiconductor wafers according to the invention and the prior art semiconductor wafers is not indicative of voids, but rather is caused by interference adjacent the peripheries of the respective semiconductor wafers.

Prior art semiconductor wafers and semiconductor wafers according to the invention were also prepared from first and second silicon wafers similar to those described with reference to Example 1, with the exception that the interface surface of the second silicon wafers were implanted with arsenic ions at respective doses of 5×10¹⁴ atoms/cm², 50 keV energy and 1×10¹⁵ atoms/cm², 50 keV energy. Substantially similar results were achieved. The semiconductor wafers according to the invention displayed no voids, while the prior art semiconductor wafers displayed voids, and the number and size of voids was greater in the prior art semiconductor wafer which was prepared with the second silicon wafer of implantation dose of 1×10¹⁵ atoms/cm², 50 keV energy, than in the prior art semiconductor wafer, the second silicon wafer of which was implanted at a dose of 5×10¹⁴ atoms/cm², 50 keV energy.

Semiconductor wafers according to the invention, and prior art semiconductor wafers were prepared with first silicon wafers of 0.006 to 0.014 ohm.cm, arsenic doped Czochralski silicon having a crystal plane orientation <111>. The second silicon wafers were similar to those described in Examples 1 to 3, and the interface surfaces of the second silicon wafers were ion implanted with arsenic ions at dose levels similar to those described in Examples 1 to 3. Micrographs were prepared by SAM imaging of the semiconductor wafers formed by the method according to the invention discussed above, and formed by the prior art method discussed above, which revealed substantially similar numbers and sizes of voids being formed in the semiconductor wafers bonded by the prior art method, and in all cases no voids were displayed in the semiconductor wafers in which the silicon wafers were bonded using the method according to the invention.

Semiconductor wafers according to the invention and prior art semiconductor wafers were prepared from first and second silicon wafers similar to the first and second silicon wafers of Examples 1 to 3, and the method according to the invention for bonding the first and second silicon wafers, and the prior art method were similar to the two respective methods already discussed with the exception that the anneal fusion bonding step of the method according to the invention and the prior art method, instead of being carried out in an oxygen diluted nitrogen atmosphere, was carried out in a nitrogen atmosphere. Similar results were obtained from micrographs prepared by SAM imaging of the semiconductor wafers according to the invention and the prior art semiconductor wafers, as were obtained in Examples 1 to 3. In other words, substantially similar amounts of voids were displayed in the prior art semiconductor wafer, and no voids were displayed in the semiconductor wafer according to the invention.

The precise reason as to why the method according to the invention prevents the formation of voids between the bonded interface surfaces is not fully understood. However, it is believed that the omission of sulphuric acid from the cleaning solutions plays a significant role in the elimination of voids. It is believed that ion implantation or diffusion of one of the interface surfaces may cause that interface surface to have a relatively high affinity for sulphuric acid and related chemical species, and thus, the sulphuric acid or the related chemical species may be absorbed through that interface surface into the silicon wafer. It is believed that the absorbed sulphuric acid and/or related species are vaporised when the abutting interface surfaces are subjected to the high temperature annealing fusion bonding, and the sulphuric acid vapour on being released through the interface surface is trapped between the respective interface surfaces, thus leading to the creation of voids between the respective interface surfaces.

It has been found that interface surfaces of silicon wafers which have been subjected to ion implantation do not appear to absorb hydrogen peroxide, ammonia or hydrofluoric acid, and it has been found that subjecting the silicon wafer, the interface surface of which had been subjected to ion implantation, to the low temperature annealing for recrystallising the interface surface further assists in the prevention of absorption of the cleaning and rinsing solutions.

It is also possible that the use of sulphuric acid in cleaning the ion implanted interface surface may roughen the interface surface, which in itself could also lead to the formation of voids, and if the interface surface which had been subjected to ion implantation were roughened, the affinity of that interface surface to sulphuric acid and its related chemical species would more than likely be enhanced.

While in the examples only the interface surface of one of the silicon wafers has been subjected to pretreatment by ion implantation, it will be appreciated that the interface surfaces of both silicon wafers could be so pretreated by ion implantation. In which case, both pretreated interface surfaces would be subjected to the low temperature anneal prior to the first cleaning step. Additionally, it will be appreciated that while the method according to the invention has been described where the interface surface of one of the silicon wafers has been subjected to pretreatment by ion implantation, the interface surface could have been subjected to a diffusion pretreatment process. Indeed, it will be appreciated that the interface surfaces of both of the silicon wafers could have been subjected to a diffusion pretreatment process. It is also envisaged that the interface surface of one of the silicon wafers may be subjected to an ion implantation pretreatment, while the interface surface of the other silicon wafer would be subjected to a diffusion pretreatment. Needless to say, the interface surface of one or both silicon wafers could have been ion implanted with any other dopant besides arsenic, for example, antimony, boron or phosphorous. The implantation dose of the dopant may vary widely, but, in general, would be in the range of 1×10¹² atoms/cm² to 1×10¹⁷ atoms/cm² at energies in the range of 20 keV to 150 keV. Alternatively, if the interface surface of one or both silicon wafers were being pretreated by diffusion they could be diffused with any suitable dopant, for example, arsenic, antimony, boron or phosphorous.

It will also be appreciated that while in the examples the interface surfaces of both silicon wafers were subjected to the first and second cleaning steps with the first and second cleaning solutions, respectively, where the interface surface of only one of the silicon wafers has been subjected to an ion implantation or a diffusion pretreatment process, it will be appreciated that only the interface surface of that silicon wafer need be subjected to the first and second cleaning steps with the first and second cleaning solutions. The interface surface of the silicon wafer which had not been subjected to pretreatment could be cleaned by any other suitable cleaning process. However, it is believed that it is preferable that the cleaning solution or solutions to which the silicon wafer with the non-pretreated interface surface is subjected should not contain sulphuric acid or its species, in order to avoid any possibility of sulphuric acid residue remaining on the non-pretreated interface surface, which could otherwise be absorbed by the pretreated interface surface during anneal bonding.

It is also envisaged that after the pretreated interface of each silicon wafer, the interface of which has been subjected to ion implantation has been subjected to the initial low temperature anneal, the annealed pretreated interface may be polished prior to the commencement of cleaning of the pretreated interface.

It is also envisaged that the initial low temperature anneal step may be omitted from the method according to the invention.

While the initial low temperature anneal has been described as being carried out at a temperature of approximately 700° C., it is envisaged that the initial low temperature anneal may be carried out at any suitable temperature sufficient for recrystallising the pretreated interface or interfaces. It is envisaged that the initial low temperature anneal may be carried out at a temperature in the range of 650° C. to 1,050° C., and more typically would be carried out at a temperature in the range of 680° C. to 850° C. In general, it is envisaged that the ideal initial low temperature anneal temperature range should be in the range of 700° C. to 750° C. The time period during which the initial low temperature anneal should be carried out should be sufficient for recrystallising the pretreated interface surface or surfaces. In general, the time period would be in the range of 30 minutes to 180 minutes, and more typically in the range of 30 minutes to 120 minutes.

While the anneal fusion bonding has been described as being carried out at a temperature of 1,150° C., it will be appreciated that the anneal fusion bonding may be carried out at any suitable temperature sufficient for fusion bonding. In general, it is envisaged that the anneal fusion bond temperature should be at least 1,000° C., and more typically in the range of 1,150° C. to 1,200° C. The time period during which the anneal fusion bonding is carried out should be sufficient for adequately fusing the two silicon wafers together, and in general, it is envisaged that the time period would range between 15 minutes and 300 minutes, and preferably, between 30 minutes and 250 minutes.

While the first and second cleaning solutions have been described as comprising specific proportions of constituents, it is envisaged that the first and second cleaning solutions may comprise the constituents in different proportions to those described. The first cleaning solution should comprise hydrogen peroxide and ammonia in effective amounts to ensure adequate cleaning. It is believed that the hydrogen peroxide may be provided in an amount in the range of 1% to 30% by volume of the first cleaning solution, and it is believed that the ammonia may be provided in an amount in the range of 0.005% to 14% by volume of the first cleaning solution. Although, it is believed that preferred results are obtained by providing the first cleaning solution with hydrogen peroxide constituting in the range of 10% to 20% by volume of the cleaning solution, and the ammonia constituting in the range of 0.01% to 1% by volume of the cleaning solution.

While the second cleaning solution has been described as comprising hydrofluoric acid in a specific amount, the hydrofluoric acid may constitute a greater or lesser proportion of the second cleaning solution, provided that the hydrofluoric acid is provided in the second cleaning solution in an effective amount for cleaning the pretreated interface surface or surfaces. It is believed that the hydrofluoric acid may constitute in the range of 0.05% to 20% by volume of the cleaning solution, although in general, it is believed that preferred results are obtained when the hydrofluoric acid constitutes in the range of 0.2% to 10% by volume of the cleaning solution.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

Other embodiments will occur to those skilled in the art and are within the following claims:

What is claimed is:

1. A method for bonding a pair of silicon wafers together at adjacent abutting interface surfaces of the respective silicon wafers to form a semiconductor wafer, wherein at least one of the interface surfaces has been pretreated by being subjected to one of an ion implantation process and a diffusion process prior to bonding, the method comprising the steps of:
subjecting each pretreated interface surface to at least one cleaning step with a cleaning solution, the cleaning solution of each cleaning step being substantially non-absorbable through the interface surface,
abutting the respective interface surfaces together, and
subjecting the silicon wafers to anneal bonding for bonding the abutting interface surfaces together.

2. A method as claimed in claim 1 in which the constituents of the cleaning solution of each cleaning step are non-absorbable through each pretreated interface surface.

3. A method as claimed in claim 1 in which the cleaning solution of each cleaning step is a solution which does not contain sulphuric acid.

4. A method as claimed in claim 1 in which the cleaning solution of each cleaning step is a solution which does not contain sulphuric acid or its species.

5. A method as claimed in claim 1 in which each pretreated interface surface is subjected to two cleaning steps, in one of the two cleaning steps the cleaning solution comprising hydrogen peroxide and ammonia, and in the other of the two cleaning steps the cleaning solution comprising hydrofluoric acid.

6. A method as claimed in claim 5 in which the cleaning solution comprising hydrogen peroxide and ammonia comprises the hydrogen perioxide and ammonia in effective amounts for cleaning each pretreated interface surface.

7. A method as claimed in claim 5 in which the cleaning solution comprising hydrogen peroxide and ammonia comprises hydrogen peroxide in an amount in the range of 1% to 30% by volume of the cleaning solution, and ammonia in an amount in the range of 0.005% to 14% by volume of the cleaning solution.

8. A method as claimed in claim 7 in which the cleaning solution comprising hydrogen peroxide and ammonia comprises hydrogen peroxide in an amount in the order of 17% by volume of the cleaning solution, and ammonia in an amount in the range of 0.01% to 0.02% by volume of the cleaning solution.

9. A method as claimed in claim 5 in which the cleaning solution comprising hydrofluoric acid comprises the hydrofluoric acid in an effective amount for cleaning each pretreated interface surface.

10. A method as claimed in claim 5 in which the cleaning solution comprising hydrofluoric acid comprises hydrofluoric acid in an amount in the range of 0.05% to 20% by volume of the cleaning solution.

11. A method as claimed in claim 10 in which the cleaning solution comprising hydrofluoric acid comprises hydrofluoric acid in an amount in the range of 0.2% to 1% by volume of the cleaning solution.

12. A method as claimed in claim 5 in which the balance of each cleaning solution is made up with water.

13. A method as claimed in claim 5 in which each pretreated interface surface is subjected to the cleaning step with the cleaning solution comprising hydrogen peroxide and ammonia before being subjected to the cleaning step with the cleaning solution comprising hydrofluoric acid.

14. A method as claimed in claim 1 in which each pretreated interface surface is subjected to a water rinse after being subject to each cleaning step for removing residue of the cleaning solutions.

15. A method as claimed in claim 1 in which each pretreated interface surface is subjected to an initial anneal step at an effective temperature for recrystallising the interface surface prior to cleaning.

16. A method as claimed in claim 15 in which each pretreated interface surface is subjected to the initial anneal step at a temperature in the range of 650° C. to 1,050° C. for recrystallising the interface surface prior to cleaning.

17. A method as claimed in claim 16 in which the initial anneal step is carried out at a temperature in the range of 700° C. to 750° C.

18. A method as claimed in claim 15 in which each pretreated interface surface is subjected to the initial anneal step for a time period sufficient for recrystallising the interface surface.

19. A method as claimed in claim 15 in which the initial anneal step is carried out for a time period in the range of 30 minutes to 180 minutes.

20. A method as claimed in claim 15 in which each pretreated interface surface is subjected to polishing after recrystallising of the interface surface by the initial anneal step.

21. A method as claimed in claim 1 in which the anneal bonding for bonding the respective silicon wafers together is carried out at an effective anneal bonding temperature to provide adequate bonding of the silicon wafers.

22. A method as claimed in claim 1 in which the anneal bonding for bonding the respective silicon wafers together is carried out at an anneal bonding temperature of at least 1,000° C.

23. A method as claimed in claim 22 in which the anneal bonding temperature is in the range of 1,150° C. to 1,200° C.

24. A method as claimed in claim 1 in which the silicon wafers are subjected to anneal bonding for a time period sufficient for adequate bonding of the silicon wafers to take place.

25. A method as claimed in claim 24 in which the silicon wafers are subjected to anneal bonding for a time period in the range of 15 minutes to 300 minutes.

26. A method as claimed in claim 1 in which the interface surface of the at least one silicon wafer is pretreated by being subjected to ion implantation for improving the electrical characteristics of the wafer.

27. A method as claimed in claim 1 in which the interface surface of the at least one silicon wafer is pretreated by being subjected to diffusion for improving the electrical characteristics of the wafer.

28. A semiconductor wafer comprising a pair of silicon wafers bonded together by anneal bonding, the bonded silicon wafers each defining an interface surface abutting the interface surface of the other silicon wafer, at least one of the interface surfaces having been subjected to a pretreatment prior to bonding by one of an ion implantation process and a diffusion process, each pretreated interface surface having been subjected to at least one cleaning step with a cleaning solution prior to the silicon wafers being subjected to the anneal bonding, the cleaning solution of each cleaning step being substantially non-absorbable through the interface surface.

29. A semiconductor wafer as claimed in claim 28 in which the cleaning solution of each cleaning step to which each pretreated interface surface is subjected is a solution which does not contain sulphuric acid.

30. A semiconductor wafer as claimed in claim 28 in which the cleaning solution of each cleaning step to which each pretreated interface surface is subjected is a solution which does not contain sulphuric acid or its species.
